(19) United States
(12) Patent Application Publication
(10) Pub. No.: US 2005/0064344 A1
(43) Pub. Date: Mar. 24, 2005

(54) Imprint lithography templates having alignment marks

(75) Inventors: Todd C. Bailey, Fishkill, NY (US); Stephen C. Johnson, Austin, TX (US); Matthew E. Colburn, Hopewell Junction, NY (US); Byung-Jin Choi, Round Rock, TX (US); Britain J. Smith, Milpitas, CA (US); John G. Ekerdt, Austin, TX (US); Carlton G. Willson, Austin, TX (US); Sidlgata V. Sreenivasan, Austin, TX (US)

Correspondence Address: MOLECULAR IMPRINTS, INC., PO BOX 81536, AUSTIN, TX, 78708-1536, US

(73) Assignee: University of Texas System Board of Regents, Austin, TX (US)

(21) Appl. No.: 10/666,527

(22) Filed: Sep. 18, 2003

(51) Int. Cl. G03F 7/00

(52) U.S. Cl. 430/320; 430/323; 101/3.1

(57) ABSTRACT

One embodiment of the present invention is an imprint template for imprint lithography that comprises alignment marks embedded in bulk material of the imprint template.

### BACKGROUND OF THE INVENTION

One or more embodiments of the present invention relate generally to imprint lithography. In particular, one or more embodiments of the present invention relate to imprint lithography templates having alignment marks.

There is currently a strong trend toward micro-fabrication, i.e., fabricating small structures and downsizing existing structures. For example, micro-fabrication typically involves fabricating structures having features on the order of micro-meters or smaller. One area in which micro-fabrication has had a sizeable impact is in microelectronics. In particular, downsizing of microelectronic structures has generally allowed such microelectronic structures to be less expensive, have higher performance, exhibit reduced power consumption, and contain more components for a given dimension relative to conventional electronic devices. Although micro-fabrication has been utilized widely in the electronics industry, it has also been utilized in other applications such as biotechnology, optics, mechanical systems, sensing devices, and reactors.

Lithography is an important technique or process in micro-fabrication that is used to fabricate semiconductor integrated electrical circuits, integrated optical, magnetic, mechanical circuits and microdevices, and the like. As is well known, lithography is used to create a pattern in a thin film carried on a substrate or wafer so that, in subsequent processing steps, the pattern can be replicated in the substrate or in another material that is deposited on the substrate. In one prior art lithography technique used to fabricate integrated circuits, the thin film is referred to as a resist. In accordance with such one prior art lithography technique, the resist is exposed to a beam of electrons, photons, or ions, by either passing a flood beam through a mask or scanning a focused beam. The beam changes the chemical structure of an exposed area of the resist so that, when immersed in a developer, either the exposed area or an unexposed area of the resist will be removed to recreate a pattern, or its obverse, of the mask or the scanning. The lithography resolution for this type of lithography is typically limited by a wavelength of the beam constituents, scattering in the resist and the substrate, and properties of the resist.

In light of the above-referenced trend in micro-fabrication, there is an ongoing need in the art of lithography to produce progressively smaller pattern sizes and a need to develop low-cost technologies for mass producing sub-50 nm structures since such technologies would have an enormous impact in many areas of engineering and science. Not only will the future of semiconductor integrated circuits be affected, but commercialization of many innovative electrical, optical, magnetic, mechanical microdevices that are superior to current devices will rely on the potential of such technologies.

Several lithography technologies have been developed to satisfy this need, but they all suffer drawbacks, and none of them can mass produce sub-50 nm lithography at low cost. For example, although electron beam lithography has demonstrated a 10 nm lithography resolution, using it for mass production of sub 50 nm structures seems economically impractical due to inherent low throughput in serial electron beam lithography tools. X-ray lithography can have high throughput and has demonstrated a 50 nm lithography resolution. However, X-ray lithography tools are rather expensive, and their ability for mass producing sub-50 nm structures is yet to be seen. Lastly, lithography technologies based on scanning probes have produced sub-10 nm structures in a very thin layer of materials. However, the practicality of such lithography technologies as a manufacturing tool is hard to judge at this point.

An imprint lithography technology for producing nanostructures with 10 nm feature sizes was proposed by Chou et al., Microelectronic Engineering, 35, (1997), pp. 237-240. To carry out such an imprint lithography process, a thin film layer is deposited on a substrate or wafer using any appropriate technique such as spin casting. Next, a mold or imprint template having a body and a molding layer that includes a plurality of features having desired shapes is formed. In accordance with a typical such imprint lithography process, the mold or imprint template is patterned with features comprising pillars, holes and trenches using electron beam lithography, reactive ion etching (RIE), and/or other suitable methods. In general, the mold or imprint template is selected to be hard relative to a softened thin film deposited on a substrate or wafer, and can be made of metals, dielectrics, semiconductors, ceramics, or their combination. For example and without limitation, the mold or imprint template may consist of a layer and features of silicon dioxide on a silicon substrate.

Next, the mold or imprint template is pressed into the thin film layer on the substrate or wafer to form compressed regions. In accordance with one such process, the features are not pressed all the way into the thin film, and hence do not contact the substrate. In accordance with another such process, top portions of the thin film may contact depressed surfaces of the mold or imprint template. The thin film may be fixed, for example and without limitation, by exposure to radiation. Then, the mold or imprint template is removed to leave a plurality of recesses formed at compressed regions in the thin film that generally conform to the shape of the features of the mold or imprint template. Next, the thin film may be subjected to a processing step in which the compressed portions of the thin film are removed to expose the substrate. This removal processing step may be carried out utilizing any suitable process such as, for example and without limitation, reactive ion etching, wet chemical etching, and so forth. As a result, dams having recesses on the surface of the substrate are formed, which recesses form reliefs that conform generally to the shape of the features of the mold or imprint template.

In accordance with a typical such imprint lithography process, the thin film layer may comprise a thermoplastic polymer. For such an example, during the compressive molding step, the thin film may be heated to a temperature to allow sufficient softening of the thin film relative to the mold or imprint template. For example, above a glass transition temperature, the polymer may have low viscosity and can flow, thereby conforming to the features of the mold or imprint template. In accordance with one such example, the thin film is PMMA spun on a silicon wafer. PMMA may be useful for several reasons. First, PMMA does not adhere well to the SiO₂ mold due to its hydrophilic surface, and good mold or imprint template release properties are important for fabricating nanoscale features. Second, PMMA shrinkage is less than 0.5% for large changes of temperature and pressure. Lastly, after removing the mold or imprint template, the PMMA in the compressed area may be removed using an oxygen plasma, exposing the underlying silicon substrate, and replicating the patterns of the mold over the entire thickness of the PMMA. Such a process has been disclosed in U.S. Pat. No. 5,772,905, which patent is incorporated herein by reference.

In accordance with another imprint lithography technology, a transfer layer is deposited on a substrate or wafer, and the transfer layer is covered with a polymerizable fluid composition. The polymerizable fluid composition is then contacted by a mold or imprint template having a relief structure formed therein such that the polymerizable fluid composition fills the relief structures in the mold or imprint template. The polymerizable fluid composition is then subjected to conditions to polymerize the polymerizable fluid composition and form a solidified polymeric material therefrom on the transfer layer. For example, the polymerizable fluid composition may become chemically cross-linked or cured so as to form a thermoset material (i.e., solidified polymeric material). The mold or imprint template is then separated from the solidified polymeric material to expose a replica of the relief structure in the mold or imprint template in the solidified polymeric material. The transfer layer and the solidified polymeric material are then processed so that the transfer layer is selectively etched relative to the solidified polymeric material. As a result, a relief image is formed in the transfer layer. The substrate or wafer upon which the transfer layer is deposited may comprise a number of different materials such as, for example and without limitation, silicon, plastics, gallium arsenide, mercury telluride, and composites thereof. The transfer layer may be formed from materials known in the art such as, for example and without limitation, thermoset polymers, thermoplastic polymers, polyepoxies, polyamides, polyurethanes, polycarbonates, polyesters, and combinations thereof. In addition, the transfer layer may be fabricated to provide a continuous, smooth, relatively defect-free surface that adheres to the solidified polymeric material. Typically, the transfer layer may be etched to transfer an image to the underlying substrate or wafer from the solidified polymeric material. The polymerizable fluid composition that is polymerized and solidified typically comprises a polymerizable material, a diluent, and other materials employed in polymerizable fluids such as, for example and without limitation, to initiators, and other materials. Polymerizable (or cross-linkable) materials may encompass various silicon-containing materials that are often present themselves in the form of polymers. Such silicon-containing materials may include, for example and without limitation, silanes, silyl ethers, silyl esters, functionalized siloxanes, silsesquioxanes, and combinations thereof. In addition, such silicon-containing materials may be organosilicons. The polymers which may be present in the polymerizable fluid composition may include various reactive pendant groups. Examples of pendant groups include, for example and without limitation, epoxy groups, ketene acetyl groups, acrylate groups, methacrylate groups, and combinations of the above. The mold or imprint template may be formed from various conventional materials. Typically, the materials are selected such that the mold or imprint template is transparent to enable the polymerizable fluid composition covered by the mold or imprint template to be exposed to an external radiation source. For example, the mold or imprint template may comprise materials such as, for example and without limitation, quartz, silicon, organic polymers, siloxane polymers, borosilicate glass, fluorocarbon polymers, metal, and combinations of the above. Lastly, to facilitate release of the mold or imprint template from the solid polymeric material, the mold or imprint template may be treated with a surface modifying agent. Surface modifying agents which may be employed include those which are known in the art, and one example of a surface modifying agent is a fluorocarbon silylating agent. These surface modifying agents or release materials may be applied, for example and without limitation, from plasma sources, a Chemical Vapor Deposition method (CVD) such as analogs of paralene, or a treatment involving a solution. Such a process has been disclosed in U.S. Pat. No. 6,334,960, which patent is incorporated herein by reference.

In accordance with another imprint lithography technology disclosed by Chou et al. in “Ultrafast and Direct Imprint of Nanostructures in Silicon,” Nature, Col. 417, pp. 835-837, June 2002 (referred to as a laser assisted direct imprinting (LADI) process), a region of a substrate is made flowable, for example and without limitation, liquefied, by heating the region with a laser. After the region has reached a desired viscosity, a mold or imprint template having a pattern thereon is placed in contact with the region. The flowable region conforms to the profile of the pattern, and is then cooled, thereby solidifying the pattern onto the substrate.

In general, all of the above-described imprint lithograpy technologies utilize a step-and-repeat process in which a pattern on a mold or imprint template is recorded on a plurality of regions on the substrate. As such, execution of a step-and-repeat process requires proper alignment of the mold or imprint template with each of these regions. Hence, a mold or imprint template typically includes alignment marks that are aligned with complementary marks on the substrate. To carry out alignment, a sensor couples to the alignment marks on the mold or imprint template and the marks on the substrate to provide an alignment signal that is used to step the mold or imprint template across the substrate.

In accordance with one well known method of alignment, the sensor may be an optical detector and the alignment marks on the mold or imprint template and the substrate may be optical alignment marks which generate a moire alignment pattern such that well known moire alignment techniques may be utilized to position the mold or imprint template relative to the substrate. Examples of such moiré alignment techniques are described by Nomura et al. in “A Moire Alignment Technique for Mix and Match Lithographic System,” J. Vac. Sci. Technol., B6(1), January/February 1988, pg. 394 and by Hara et al. in “An Alignment Technique Using Diffracted Moire Signals,” J. Vac. Sci, Technol., B7(6), November/December 1989, pg. 1977. Further, in accordance with another well known method of alignment, the alignment marks on the mold or imprint template and the substrate may comprise plates of a capacitor such that the sensor detects a capacitance between the marks. Using such a technique, alignment may be achieved by moving the mold or imprint template in a plane to maximize the capacitance between the alignment marks on the mold or imprint template and the substrate.

Currently, alignment marks used in imprint lithography are etched into the topography of the mold or imprint template. This is problematic since such alignment marks are typically formed of the same material as that of the mold or imprint template itself. As such, since the index of refraction of the mold or imprint template is substantially the same as that of a thin film used to transfer the imprint pattern (at least to manufacturing tolerances), an ability to resolve alignment marks in the mold or imprint template is severely hindered.

In light of the above, there is a need for alignment marks useful in imprint lithography that enable reliable alignment of molds or imprint template and a method of fabricating molds or imprint templates having such alignment marks.

### SUMMARY OF THE INVENTION

One or more embodiments of the present invention satisfy one or more of the above-identified needs in the art. In particular, one embodiment of the present invention is an imprint template for imprint lithography that comprises alignment marks embedded in bulk material of the imprint template.

### BRIEF DESCRIPTION OF THE DRAWING

FIG. 1 shows a pictorial representation of one type of imprint lithography system utilized to carry out the one type of imprint lithography process illustrated in FIGS. 2A-2E;

FIGS. 2A-2E illustrate a step-by-step sequence for carrying out one type of imprint lithography process;

FIGS. 3A-3F illustrate a step-by-step sequence for fabricating alignment marks in an imprint template in accordance with one or more embodiments of the present invention; and

FIG. 4 shows a pictorial representation of how an imprint template that is fabricated in accordance with one or more embodiments of the present invention is used.

### DETAILED DESCRIPTION OF THE INVENTION

One or more embodiments of the present invention relate to an imprint template or mold for imprint lithography that comprises alignment marks embedded in bulk material of the imprint template. In addition, in accordance with one or more further embodiments of the present invention that are useful for optical alignment techniques, the alignment marks are fabricated from a material whose index of refraction is different from that of at least the bulk material of the imprint template surrounding the alignment marks. Still further, in accordance with one or more further embodiments of the present invention, the alignment marks are fabricated from a material whose index of refraction is different from that of at least the bulk material of the imprint template surrounding the alignment marks and that of the material into which an imprint is made in carrying out an imprint lithography process. Advantageously, in accordance with such embodiments, differences in indices of refraction enhance optical contrast between the alignment marks and surrounding material, thereby facilitating the ease and reliability of optical alignment techniques.

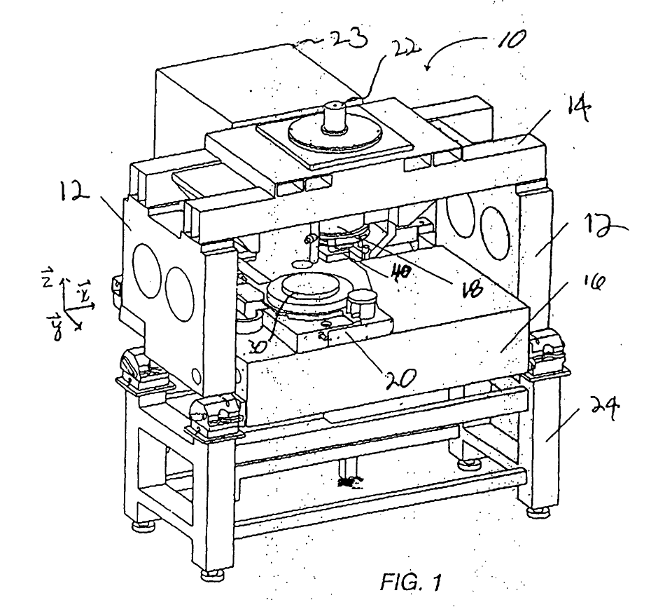

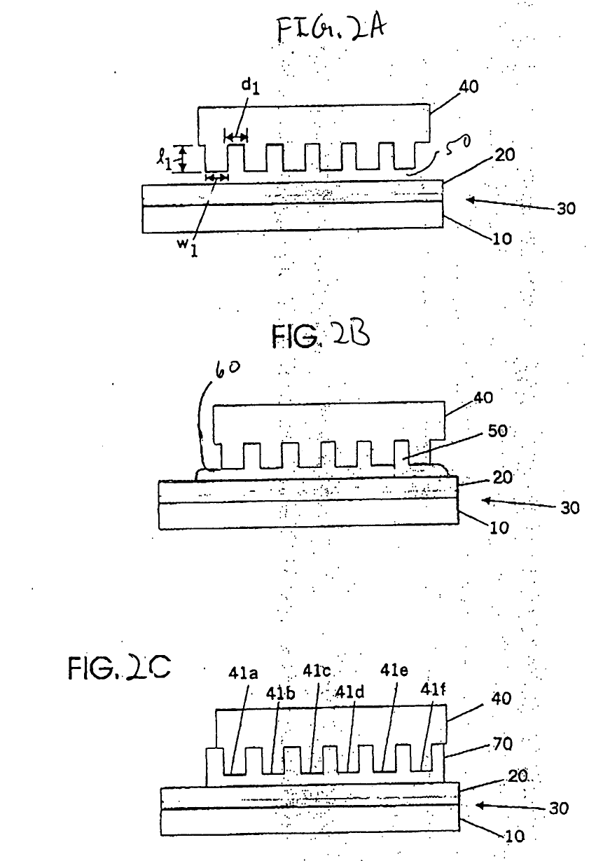

FIG. 1 shows one type of imprint lithographic system, imprint lithography system 10, utilized to carry out one type of imprint lithography process illustrated in FIGS. 2A-2E. As shown in FIG. 1, imprint lithography system 10 includes a pair of spaced-apart bridge supports 12 having a bridge 14 and a stage support 16 extending therebetween. As further shown in FIG. 1, bridge 14 and stage support 16 are spaced apart, and imprint head 18 is coupled to, and extends from, bridge 14 towards stage support 16. As further shown in FIG. 1, motion stage 20 is position upon stage support 16 to face imprint head 18, and motion stage 20 is configured to move with respect to stage support 16 along X and Y axes. As further shown in FIG. 1, radiation source 22 is coupled to bridge 14, and power generator 23 is connected to radiation source 22. Radiation source 22 is configured to output actinic radiation, for example and without limitation UV radiation, upon motion stage 20.

As further shown in FIG. 1, structure 30 is positioned on motion stage 20 and imprint template 40 is connected to imprint head 18. As will be set forth in more detail below, imprint template 40 includes a plurality of features defined by a plurality of spaced-apart recessions and protrusions. The plurality of features defines an original pattern that is to be transferred into structure 30 positioned on motion stage 20. To do that, imprint head 18 is adapted to move along the Z axis and to vary a distance between imprint template 40 and structure 30. In this manner, the features on mold 40 may be imprinted into a flowable region of structure 30. Radiation source 22 is located so that imprint template 40 is positioned between radiation source 22 and structure 30. As a result, imprint template 40 may be fabricated from material that allows it to be substantially transparent to radiation output from radiation source 22.

FIGS. 2A-2E illustrate a step-by-step sequence for carrying out one type of imprint lithography process utilizing, for example and without limitation, imprint lithography system 10 shown in FIG. 1. As shown in FIG. 2A, structure 30 includes substrate or wafer 10 having transfer layer 20 deposited thereon. In accordance with one or more embodiments of this process, transfer layer 20 may be a polymeric transfer layer that provides a substantially continuous, planar surface over substrate 10. In accordance with one or more further embodiments of this imprint lithography process, transfer layer 20 may be a material such as, for example and without limitation, an organic thermoset polymer, a thermoplastic polymer, a polyepoxy, a polyamide, a polyurethane, a polycarbonate, a polyester, and combinations thereof. As further shown in FIG. 2A, imprint template 40 is aligned over transfer layer 20 such that gap 50 is formed between imprint template 40 and transfer layer 20. In accordance with one or more embodiments of this imprint lithography process, imprint template 40 may have a nanoscale relief structure formed therein having an aspect ratio ranging, for example and without limitation, from about 0.1 to about 10. Specifically, the relief structures in imprint template 40 may have a width w₁ that ranges, for example and without limitation, from about 10 nm to about 5000 μm, and the relief structures may be separated from each other by a distance d₁ that ranges, for example and without limitation, from about 10 nm to about 5000 μm. Further, in accordance with one or more embodiments of this imprint lithography process, imprint template 40 may comprise a material such as, for example and without limitation, a metal, silicon, quartz, an organic polymer, a siloxane polymer, borosilicate glass, a fluorocarbon polymer, and combinations thereof. In addition, in accordance with one or more further embodiments of this imprint lithography process, a surface of imprint template 40 may be treated with a surface modifying agent such as a fluorocarbon silylating agent to promote release of imprint template 40 after transfer of the feature pattern. In further addition, in accordance with one or more further embodiments of this imprint lithography process, the step of treating the surface of imprint template 40 may be carried out utilizing a technique such as, for example and without limitation, a plasma technique, a chemical vapor deposition technique, a solution treatment technique, and combinations thereof.

As shown in FIG. 2B, polymerizable fluid composition 60 contacts transfer layer 20 and imprint template 40 to fill gap 50 therebetween. Polymerizable fluid composition 60 may have a low viscosity such that it may fill gap 50 in an efficient manner, for example and without limitation, a viscosity in a range, for example and without limitation, from about 0.01 cps to about 100 cps measured at 25° C. In accordance with one or more embodiments of this imprint lithography process, polymerizable fluid composition 60 may comprise a silicon-containing material such as, for example and without limitation, an organosilane. Further, in accordance with one or more further embodiments of this imprint lithography process, polymerizable fluid composition 60 may comprise a reactive pendant group selected, for example and without limitation, from an epoxy group, a ketene acetyl group, an acrylate group, a methacrylate group, and combinations thereof. Polymerizable fluid composition 60 may also be formed using any known technique such as, for example and without limitation, a hot embossing process disclosed in U.S. Pat. No. 5,772,905, or a laser assisted direct imprinting (LADI) process of the type described by Chou et al. in “Ultrafast and Direct Imprint of Nanostructures in Silicon,” Nature, Col. 417, pp. 835-837, June 2002. Still further, in accordance with one or more further embodiments of this imprint lithography process, polymerizable fluid composition 60 may be a plurality of spaced-apart discrete beads deposited on transfer layer 20.

Next, referring to FIG. 2C, imprint template 40 is moved closer to transfer layer 20 to expel excess polymerizable fluid composition 60 such that edges 41a through 41f of imprint template 40 come into contact with transfer layer 20. Polymerizable fluid composition 60 has requisite properties to completely fill recessions in imprint template 40. Polymerizable fluid composition 60 is then exposed to conditions sufficient to polymerize the fluid. For example, polymerizable fluid composition 60 is exposed to radiation output from radiation source 22 that is sufficient to polymerize the fluid composition and form solidified polymeric material 70 shown in FIG. 2C. As those of ordinary skill in the art will readily appreciate, embodiments of the present invention are not restricted to such a method of polymerizing or setting fluid composition 60. In fact, it is within the spirit of the present invention that other means for polymerizing fluid composition 60 may be employed such as, for example and without limitation, heat or other forms of radiation. The selection of a method of initiating the polymerization of fluid composition 60 is known to one skilled in the art, and typically depends on the specific application which is desired.

As shown in FIG. 2D, imprint template 40 is then withdrawn to leave solidified polymeric material 70 on transfer layer 20. By varying the distance between imprint template 40 and structure 30, the features in solidified polymeric material 70 may have any desired height, dependent upon the application. Transfer layer 20 may then be selectively etched relative to solid polymeric material 70 such that a relief image, corresponding to the image in imprint template 40, is formed in transfer layer 20. In accordance with one or more embodiments of this imprint lithography process, the etching selectivity of transfer layer 20 relative to solid polymeric material 70 may range, for example and without limitation, from about 1.5:1 to about 100:1. Further, in accordance with one or more further embodiments of this imprint lithography process, the selective etching may be carried out by subjecting transfer layer 20 and solid polymeric material 70 to an environment such as, for example and without limitation, an argon ion stream, an oxygen-containing plasma, a reactive ion etching gas, a halogen-containing gas, a sulfur dioxide-containing gas, and combinations of the above.

Lastly, as shown in FIG. 2E, residual material 90 might be present in gaps within the relief image in transfer layer 20 after the above-described process steps, which residual material 90 may be in the form of: (1) a portion of polymerizable fluid composition 60, (2) a portion of solid polymeric material 70, or (3) combinations of (1) and (2). As such, in accordance with one or more embodiments of this imprint lithography process, processing may further comprise a step of subjecting residual material 90 to conditions such that residual material 90 is removed (e.g., a clean-up etch). The clean-up etch may be carried out using known techniques such as, for example and without limitation, argon ion stream, a fluorine-containing plasma, a reactive ion etch gas, and combinations thereof. Additionally, it should be appreciated that this step may be carried out during various stages of the imprint lithography process. For example, removal of the residual material may be carried out prior to the step of subjecting transfer layer 20 and solid polymeric material 70 to an environment wherein transfer layer 20 is selectively etched relative to solid polymeric material 70.

As should be readily appreciated by those of ordinary skill in the art, structure 30 includes a plurality of regions in which the pattern of imprint template 40 will be recorded in a step-and-repeat process. As is known, proper execution of such a step-and-repeat process includes proper alignment of imprint template 40 with each of the plurality of regions. To that end, imprint template 40 includes alignment marks and one or more of regions of structure 30 includes alignment marks or fiducial marks. By ensuring that the alignment marks on imprint template 40 are properly aligned with the alignment or fiducial marks on structure 30, proper alignment of imprint template 40 with each of the plurality of regions will be assured. To that end, in accordance with one or more embodiments of this imprint lithography process, machine vision devices (not shown) may be employed to sense the relative alignment between the alignment marks on imprint template 40 and the alignment or fiducial marks on structure 30. Such machine vision devices may be any one of a number of machine vision devices that are well known to those of ordinary skill in the art for use in detecting alignment marks and providing an alignment signal. Then, utilizing the alignment signal, imprint lithography system 10 will move imprint template 40 relative to structure 30 in a manner that is well known to those of ordinary skill in the art to provide alignment to within a predetermined degree of tolerance.

In accordance with one or more embodiments of the present invention, alignment marks are embedded in an imprint template. In addition, in accordance with one or more further embodiments of the present invention that are useful for optical alignment techniques, the alignment marks are fabricated from a material whose index of refraction is different from that of at least the bulk material of the imprint template surrounding the alignment marks. Still further, in accordance with one or more further embodiments of the present invention that are useful for optical alignment techniques, the alignment marks are fabricated from a material whose index of refraction is different from that of at least the bulk material of the imprint template surrounding the alignment marks and that of the material into which an imprint is made in carrying out an imprint lithography process. Still further, as will be described in further detail below, in accordance with one or more embodiments of the present invention that are useful in forming alignments marks in a substrate utilizing radiation to polymerize a material, a distance between a surface of the imprint template and the alignments marks is large enough to enable the radiation utilized to polymerize the material to diffract around the alignment marks and polymerize material disposed thereunder (i.e., the distance is large enough so that a sufficient amount of the polymerizing radiation irradiates a region under the surface to polymerize material disposed therein). An appropriate distance for a particular application may be determined readily by one of ordinary skill in the art without undue experimentation. Still further, in accordance with one or more further embodiments of the present invention, the alignment marks may be embedded into the imprint template by covering them with the same material used to fabricate the imprint template itself, thereby assuring compatibility with a surface modifying release layer applied to the imprint template.

Advantageously, in accordance with one or more embodiments of the present invention, for imprint templates used in imprint technology processes where radiation is used to cure a material into which an imprint is to be made, embedding the alignment marks enables the curing radiation to cure the material directly thereunder. In addition, embedding the alignment marks is advantageous even for imprint templates used in imprint technology processes where radiation is not used to cure a material. This is so because embedding alignments marks (such as alignment marks fabricated, for example and without limitation, from a metal or other material) within the imprint template enables release layers (such as, for example and without limitation, covalently bonded, thin, fluorocarbon films) to be deposited on a surface of the imprint template to aid in releasing the imprint template from the substrate and cured polymer following polymerization without diminishing the reactivity of the release layer with the imprint template. As a result, defects in repeated imprints are reduced or eliminated.

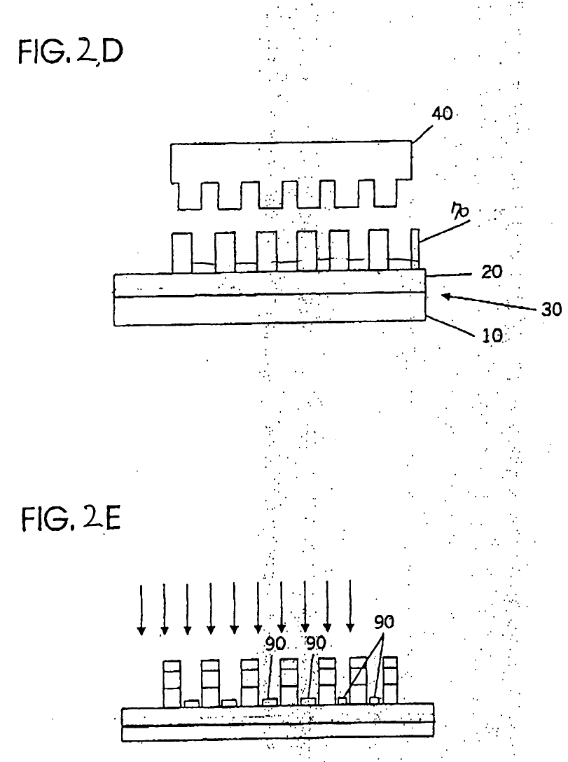

FIGS. 3A-3F illustrate a step-by-step sequence for fabricating alignment marks in an imprint template in accordance with one or more embodiments of the present invention. Note, FIGS. 3A-3F only illustrate fabricating a portion of the imprint template that contains alignment marks. Portions of the imprint template that contain imprint pattern topography used, for example and without limitation, to fabricate devices are omitted for ease of understanding the one or more embodiments of the present invention.

FIG. 3A shows imprint template blank 300 on which pattern etch mask 310 has been fabricated in accordance with any one of a number of methods that are well known to those of ordinary skill in the art. For example and without limitation, pattern etch mask 310 may a resist and the bulk material of imprint template blank 300 may be comprised of, for example and without limitation, SiO₂. Next, FIG. 3B shows imprint template blanks 400 and 401, respectively, that were fabricated by etching alignment features into imprint template blank 300 in accordance with any one of a number of etching methods that are well known to those of ordinary skill in the art. As described below, imprint template blank 400 will be processed further to fabricate an imprint template having featured-surface alignment marks, i.e., an imprint template that will be used in alignment and in forming alignment marks in a substrate that correspond to the alignment marks in the imprint template. As will also be described below, imprint template blank 401 will be processed further to fabricate an imprint template having smooth-surface alignment marks, i.e., an imprint template that will be use in alignment (note that imprint features for forming alignment marks on a substrate for such an imprint template may be disposed in another location of the imprint template).

Next, FIG. 3C shows imprint template blanks 400 and 401 after anisotropic deposition of material, for example, a metal or another material having a predetermined index of refraction, in accordance with any one of a number of methods that are well known to those of ordinary skill in the art such as, for example and without limitation, sputtering, to form imprint templates 410 and 411, respectively. As shown in FIG. 3C, material portions 405₁-405ₙ and 406₁-406ₙ, respectively, are disposed at the bottom of alignment features of imprint template blanks 410 and 411, respectively. Next, FIG. 3D shows imprint template blanks 410 and 411 after deposition of material, for example and without limitation, the same material as the bulk material of the remainder of the imprint templates, for example, SiO₂ in accordance with any one of a number of methods that are well known to those of ordinary skill in the art to form imprint templates 420 and 421, respectively. The deposition step embeds alignment marks 405₁-405n and 406₁-406n at a distance from a surface of imprint templates 420 and 421 that is large enough to enable radiation utilized to polymerize a material in a particular application to diffract around the alignment marks and polymerize material disposed thereunder. An appropriate distance for the particular application may be determined readily by one of ordinary skill in the art without undue experimentation. As one of ordinary skill in the art can readily appreciate, in accordance with one or more further embodiments of the present invention, various ones of the alignments marks may be fabricated to be disposed at different depths from a surface of the imprint template by appropriately modifying the above-described steps in a manner that may be determined readily by one of ordinary skill in the art without undue experimentation.

Next, FIG. 3E shows imprint template blanks 420 and 421 after a lift-off process that removes pattern etch mask 310 and any films deposited thereon in accordance with any one of a number of methods that are well known to those of ordinary skill in the art to form imprint templates 430 and 431, respectively. At this point imprint templates 430 and/or 431 may be treated with a surface modifying agent in accordance with any one of a number of methods that are well known to those of ordinary skill in the art such as, for example and without limitation, by depositing a release film on imprint templates 430 and/or 431. Lastly, FIG. 3F shows imprint templates 430 and 431 inverted and ready for use in an imprinting lithography process. As one can readily appreciate from FIG. 3F, imprint template 430 contains imprinting features that can be used to transfer the alignment marks to a substrate. In addition, as one can readily appreciate, because the alignment marks are embedded into the imprint template, radiation used, for example, to polymerize a layer to form the alignment marks can diffract around the alignment marks in the imprint template to carry out that function.

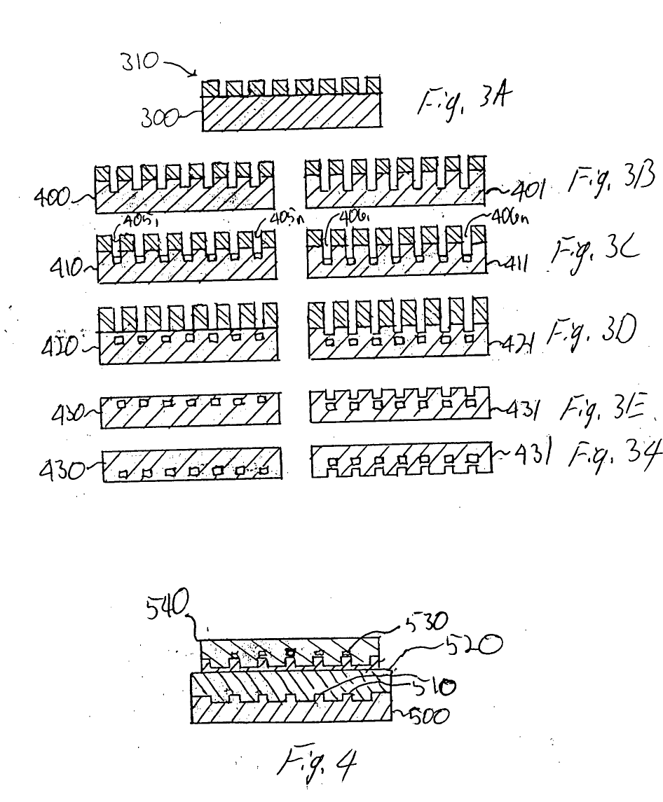

FIG. 4 shows a pictorial representation of how an imprint template that is fabricated in accordance with one or more embodiments of the present invention is used. Note, FIG. 4 only shows portions of an imprint template and a substrate that contain alignment marks. Portions of the imprint template and the substrate that contain imprint pattern topography used, for example and without limitation, to fabricate devices are omitted for ease of understanding the one or more embodiments of the present invention. As shown in FIG. 4, substrate 500 contains alignments marks 510 that were formed during previous steps in fabricating, for example and without limitation, an integrated circuit. As further shown in FIG. 4, layer 520 disposed over substrate 500 is a transfer layer of the type described previously herein. For example and without limitation, the transfer layer is a polymer layer. As further shown in FIG. 4, layer 530 disposed over transfer layer 520 is, for example, a polymerizable fluid composition layer into which an imprint is to be made during this step of fabrication. Lastly, as shown in FIG. 4, imprint template 540 having embedded alignment marks 530, for example and without limitation, metal alignment marks, is disposed over and in position to imprint layer 530.

Although various embodiments that incorporate the teachings of the present invention have been shown and described in detail herein, those skilled in the art can readily devise many other varied embodiments that still incorporate these teachings. For example, as one of ordinary skill in the art can readily appreciate, embodiments of the present invention are not restricted to any particular type of imprint lithography technology or to any particular type of alignment technology.

1. An imprint template for imprint lithography that comprises:
alignment marks embedded in bulk material of the imprint template.

2. The imprint template of claim 1 wherein one or more of the alignment marks are spaced one or more predetermined distances from a surface of the imprint template.

3. The imprint template of claim 1 wherein the one or more predetermined distances is sufficient to enable predetermined radiation to irradiate predetermined regions disposed under a surface of the imprint template.

4. The imprint template of claim 1 wherein the alignment marks are fabricated from a material whose index of refraction is different from that of at least the bulk material of the imprint template surrounding the alignment marks.

5. The imprint template of claim 1 wherein the alignment marks are fabricated from a material whose index of refraction is different from that of at least the bulk material of the imprint template surrounding the alignment marks and that of a material into which an imprint is made.

6. The imprint template of claim 1 wherein the alignment marks are metal.

7. The imprint template of claim 1 wherein a material disposed between the alignments marks and a surface of the imprint template is the same material used to form other portions of the bulk material of the imprint template.

8. The imprint template of claim 1 wherein the surface of the imprint template includes a release layer.

9. The imprint template of claim 8 wherein the release layer is a fluorocarbon release layer.

10. The imprint template of claim 8 wherein the release layer is a covalently bonded, thin, fluorocarbon film.

11. An imprint template for imprint lithography that comprises:
alignment marks embedded in bulk material of the imprint template, with said bulk material being transparent to radiation having a predetermined wavelength and said alignment marks being are spaced one or more predetermined distances from a surface of the imprint template.

12. The imprint template of claim 11 wherein the one or more predetermined distances is sufficient to enable said radiation to irradiate predetermined regions in superimposition with the imprint template.

13. The imprint template of claim 12 wherein the alignment marks are fabricated from a material whose index of refraction is different from that of at least the bulk material of the imprint template surrounding the alignment marks.

14. The imprint template of claim 13 wherein the index of refraction of the material differs from an index of refraction a layer into which an imprint is made.

15. The imprint template of claim 14 wherein the alignment marks are metal.

16. The imprint template of claim 15 wherein the surface of the imprint template includes a release layer.

17. The imprint template of claim 16 wherein the release layer is a fluorocarbon release layer.

18. The imprint template of claim 16 wherein the release layer is a covalently bonded, thin, fluorocarbon film.

19. A method for fabricating an imprint template for imprint lithography that comprises steps of:
depositing a mask on an imprint template;
etching alignment features through the mask into the imprint template;
depositing alignment marks into the alignment features;
depositing a material over the alignment marks; and
removing the mask.

20. The method of claim 12 which further comprises treating the surface of the imprint template.
